(19) United States
(12) Patent Application Publication
(10) Pub. No.: US 2025/0183194 A1
(43) Pub. Date: Jun. 5, 2025

(54) SEMICONDUCTOR PACKAGE

(71) Applicant: SAMSUNG ELECTRONICS CO., LTD., Suwon-si (KR)

(72) Inventors: Jingyu BAE, Suwon-si (KR); Minki KIM, Suwon-si (KR); Hyuekjae LEE, Suwon-si (KR)

(73) Assignee: SAMSUNG ELECTRONICS CO., LTD., Suwon-si (KR)

(21) Appl. No.: 18/778,272

(22) Filed: Jul. 19, 2024

(30) Foreign Application Priority Data
Dec. 4, 2023 (KR) 10-2023-0173427

(51) Int. Cl. H01L 23/00; H01L 21/306; H01L 23/13; H01L 23/48; H01L 23/528; H01L 25/18; H10B 80/00

(52) U.S. Cl. CPC H01L 23/562; H01L 23/13; H01L 23/481; H01L 23/5283; H01L 24/05; H01L 24/08; H01L 21/30625; H01L 24/02; H01L 24/03; H01L 24/96; H01L 24/97; H01L 25/18; H01L 2224/02331; H01L 2224/0235; H01L 2224/02372; H01L 2224/02381; H01L 2224/03002; H01L 2224/03614; H01L 2224/03622; H01L 2224/0363; H01L 2224/05009; H01L 2224/05187; H01L 2224/05548; H01L 2224/05687; H01L 2224/08145; H01L 2224/08225; H01L 2224/96; H01L 2224/97; H01L 2225/06544; H01L 2924/1431; H01L 2924/1436; H10B 80/00

(57) ABSTRACT

There is provided a semiconductor package including a first semiconductor chip having lower connection pads provided on a lower surface thereof, and upper connection pads provided on an upper surface thereof and electrically connected to the lower connection pads, and at least one second semiconductor chip provided on the first semiconductor chip in a vertical direction, and having lower pads provided on a lower surface thereof and directly bonded to the upper connection pads of the first semiconductor chip, upper pads provided on the upper surface thereof, and through-silicon vias electrically connecting the lower pads and the upper pads. The at least one second semiconductor chip includes a semiconductor substrate having a first width and a device layer having a second width, smaller than the first width.

### CROSS-REFERENCE TO RELATED APPLICATION(S)

This application is based on and claims benefit of priority to Korean Patent Application No. 10-2023-0173427 filed on Dec. 4, 2023, in the Korean Intellectual Property Office, the disclosure of which is incorporated herein by reference in its entirety.

### BACKGROUND

### 1. Field

The disclosure relates to a semiconductor package.

### 1. DESCRIPTION OF RELATED ART

Electronic devices are becoming smaller and lighter according to the development of the electronics industry and user demand, and as such, a semiconductor package used in electronic devices are required to high performance and high capacity, while having reduced weight and reduced size to satisfy with miniaturization of the electronic devices. In order to implement high performance and high capacity, together with the miniaturization and weight reduction of the semiconductor packages, research and development of semiconductor chips including a through-silicon via (TSV) and semiconductor packages in which the semiconductor chips are stacked are continuously being conducted.

### SUMMARY

One or more aspects of the disclosure provide a semiconductor package having semiconductor chips stacked with improved structural reliability.

According to an aspect of the disclosure, there is provided a semiconductor package including: a first semiconductor chip having first connection pads provided on a first surface of the first semiconductor chip, and second connection pads provided on a second surface of the first semiconductor chip, the second connection pads electrically connected to the first connection pads; and at least one second semiconductor chip provided on the first semiconductor chip in a vertical direction, the at least one second semiconductor chip including: a semiconductor substrate having a first width in a first direction, a device layer provided on a first surface of the semiconductor substrate, the device layer including one or more circuit structures and having a second width smaller than the first width in the first direction, first pads provided on a first surface of the device layer and directly bonded to the second connection pads of the first semiconductor chip, second pads provided on a second surface of the semiconductor substrate, and through-silicon vias provided in the semiconductor substrate and configured to electrically connect the first pads and the second pads, the through-silicon vias being connected to the one or more circuit structures.

According to another aspect of the disclosure, there is provided a semiconductor package including: a first semiconductor chip having first connection pads provided on a first surface of the first semiconductor chip, and second connection pads provided on a second surface of the first semiconductor chip, the second connection pads electrically connected to the first connection pads; and a plurality of second semiconductor chips provided on the first semiconductor chip in a vertical direction, each of the plurality of second semiconductor chips including: a semiconductor substrate having a first width in a first direction, a device layer provided on a first surface of the semiconductor substrate, the device layer including one or more circuit structures and having a second width smaller than the first width in the first direction, first pads provided on a first surface of the device layer, second pads provided on a second surface of the semiconductor substrate, and through-silicon vias provided in the semiconductor substrate and configured to electrically connect the first pads and the second pads, the through-silicon vias being connected to the one or more circuit structures, wherein the first pads of a lowermost second semiconductor chip, among the plurality of second semiconductor chips, are directly bonded to the second connection pads, and the second pads of the plurality of second semiconductor chips are directly bonded to the first pads of an adjacent second semiconductor chip, among the plurality of second semiconductor chips, and wherein a recess portion is formed in a side surface of the semiconductor substrate and a side surface of the device layer.

According to another aspect of the disclosure, there is provided a semiconductor package including: a first semiconductor chip having first connection pads provided on a first surface of the first semiconductor chip, and second connection pads provided on a second surface of the first semiconductor chip, the second connection pads electrically connected to the first connection pads; and a plurality of second semiconductor chips provided on the first semiconductor chip in a vertical direction, each of the plurality of second semiconductor chips including: a semiconductor substrate having a first area smaller than a second area of the first semiconductor chip, a device layer provided on a first surface of the semiconductor substrate, the device layer including one or more circuit structures and having a third area smaller than the first area, first pads provided on a second surface of the semiconductor substrate, second pads provided on a second surface of the semiconductor substrate, and through-silicon vias provided in the semiconductor substrate and configured to electrically connecting the first pads and the second pads, the through-silicon vias being connected to the one or more circuit structures, wherein the first pads of a lowermost second semiconductor chip, among the plurality of second semiconductor chips, are directly bonded to the second connection pads, and the second pads of the plurality of second semiconductor chips are directly bonded to the first pads of an adjacent second semiconductor chip, among the plurality of second semiconductor chips, and wherein an edge region of the semiconductor substrate protrudes outside a side surface of the device layer.

According to one or more aspects of the disclosure, structural distortion of a package may be compensated by controlling each layer to have a different width based on a difference in a coefficient of thermal expansion between layers so as to compensate for different coefficients of thermal expansion (CTE) of different materials between each layer as stacked semiconductor chips increase. According to one or more aspects of the disclosure, by forming a step portion in an edge region, defects such as an occurrence of poor bonding in an edge region having poor morphology, or an occurrence of voids may be removed. According to one or more aspects of the disclosure, cracks in a base substrate in a lower end may be prevented due to accumulation of morphological stress in the edge region, thereby providing a highly reliable semiconductor package structure.

Advantages and effects of the disclosure are not limited to the foregoing content and may be more easily understood in the process of describing a specific example embodiment of the disclosure.

### BRIEF DESCRIPTION OF DRAWINGS

The above and other aspects, features, and advantages of the disclosure will be more clearly understood from the following detailed description, taken in conjunction with the accompanying drawings, in which:

FIG. 1 is a side cross-sectional view illustrating a semiconductor package according to an example embodiment of the disclosure;

FIG. 2 is a plan view illustrating the semiconductor package of FIG. 1;

FIGS. 3A and 3B are partially enlarged views illustrating portions “A” and “B” of FIG. 1, respectively;

FIG. 4 is a partially enlarged view illustrating a semiconductor package according to an example embodiment of the disclosure;

FIG. 5 is a side cross-sectional view illustrating a semiconductor package according to an example embodiment of the disclosure;

FIG. 6 is a side cross-sectional view illustrating a semiconductor package according to an example embodiment of the disclosure;

FIG. 7 is a side cross-sectional view illustrating a semiconductor package according to an example embodiment of the disclosure;

FIG. 8 is a side cross-sectional view illustrating a semiconductor package according to an example embodiment of the disclosure;

FIGS. 9A to 9H are cross-sectional views of main processes for illustrating a method of manufacturing a semiconductor chip according to an example embodiment of the disclosure; and

FIGS. 10A to 10C are cross-sectional views of main processes for illustrating a method of manufacturing a semiconductor package according to an example embodiment of the disclosure.

### DETAILED DESCRIPTION

Hereinafter, example embodiments of the disclosure will be described with reference to the accompanying drawings.

The following specific embodiments are provided to assist readers in obtaining a full understanding of methods, devices, and/or systems described herein. However, various changes, modifications, and equivalents of the methods, devices, and/or systems described herein will be clear upon understanding the disclosure of the present application. For example, orders of operations described herein are merely exemplary and the disclosure is not limited to those set forth herein, but rather may be altered as will be clear upon an understanding of the disclosure of the present application, except for operations that must occur in a particular order. In addition, descriptions of features known in the art may be omitted for greater clarity and brevity.

The features described herein may be implemented in different forms and should not be construed as being limited to examples described herein. Rather, the examples described herein have been provided to illustrate only some of many feasible ways of realizing the methods, devices, and/or systems described herein, many feasible ways will be clear upon an understanding of the disclosure of the present application.

The terms used herein are used only to describe various examples and will not be used to limit the disclosure. Unless the context clearly indicates otherwise, the singular form is also intended to include the plural form. The terms “comprising,” “including,” and “having” indicate the presence of recited features, quantities, operations, components, elements, and/or combinations thereof, but do not preclude the presence or addition of one or more other features, quantities, operations, components, elements, and/or combinations thereof.

Unless otherwise defined, all terms used herein, including technical and scientific terms, have the same meanings as those commonly understood by those of ordinary skill in the art to which the disclosure pertains after understanding the disclosure. Unless expressly so defined herein, terms (e.g., terms defined in a general-purpose dictionary) should be interpreted as having a meaning consistent with their meaning in the context of the relevant field and the disclosure, and should not be interpreted ideally or in an overly formalistic manner.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment (e.g., as to what an example or embodiment may include or implement) means that at least one example or embodiment exists where such a feature is included or implemented, while all example embodiments are not limited thereto.

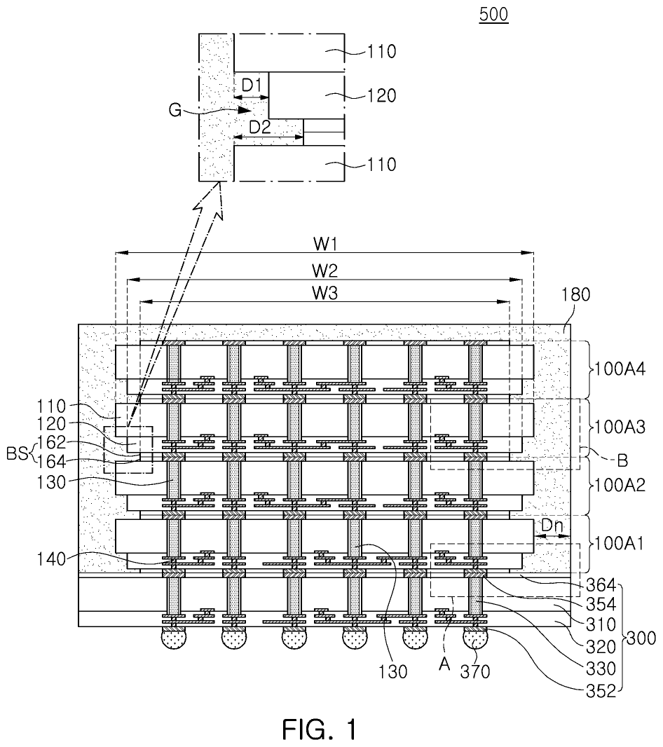

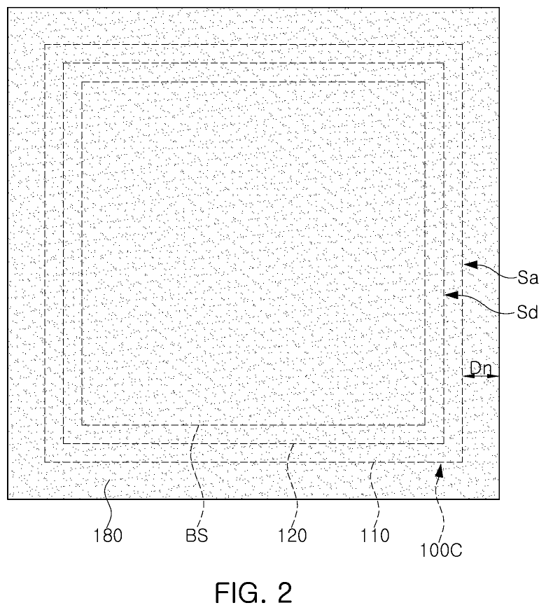

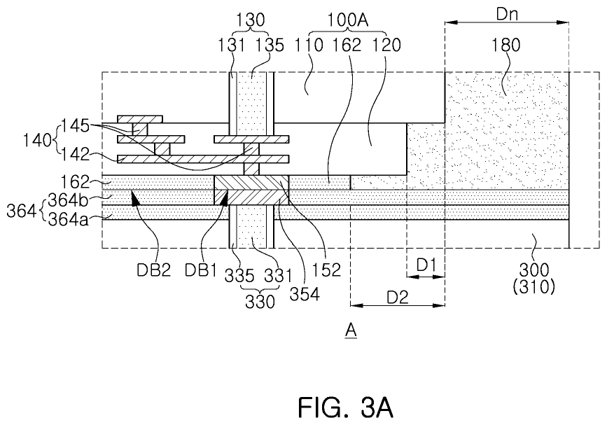

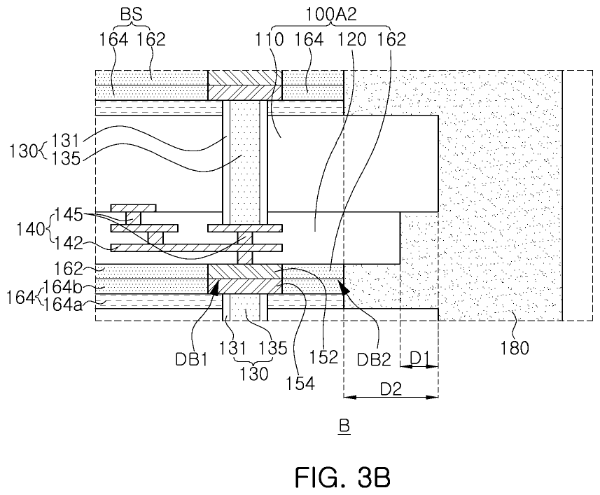

FIG. 1 is a side cross-sectional view illustrating a semiconductor package according to an example embodiment of the disclosure, FIG. 2 is a plan view illustrating the semiconductor package of FIG. 1, and FIGS. 3A and 3B are partially enlarged views illustrating portions “A” and “B” of FIG. 1, respectively.

Referring to FIG. 1, a semiconductor package 500 may include a base structure 300, and a plurality of semiconductor chips 100A1, 100A2, 100A3 and 100A4 provided on the base structure 300. The plurality of semiconductor chips may include a first semiconductor chip 100A1, a second semiconductor chip 100A2, a third semiconductor chip 100A3 and a fourth semiconductor chip 100A4. According to an example embodiment, the plurality of semiconductor chips 100A1, 100A2, 100A3 and 100A4 may be stacked in a vertical direction on the base structure 300. According to an example embodiment, the semiconductor package 500 may further include a cover chip or a dummy chip on the stack of the plurality of semiconductor chips 100A1, 100A2, 100A3 and 100A4, but the disclosure is not limited thereto.

According to an embodiment, the plurality of stacked semiconductor chips may include, but is not limited to, four semiconductor chips 100A1, 100A2, 100A3 and 100A4. The plurality of semiconductor chips 100A1, 100A2, 100A3 and 100A4 may have a same size. For example, an area of each of the plurality of semiconductor chips 100A1, 100A2, 100A3 and 100A4 may be same. In an example case in which the cover chip or the dummy chip is further included in the stack of the plurality of semiconductor chips 100A1, 100A2, 100A3 and 100A4, the cover chip may also have a same area as each of the semiconductor chips 100A1, 100A2, 100A3 and 100A4. The cover chip may also include a semiconductor chip, but the disclosure is not limited thereto. For example, as illustrated in FIG. 1, the plurality of semiconductor chips 100A1, 100A2, 100A3 and 100A4 may have the same width as a first width W1. Moreover, according to an embodiment, each of the plurality of semiconductor chips 100A1, 100A2, 100A3 and 100A4 may have the same thickness.

However, the disclosure is not limited thereto, and as such, according to another embodiment, a thickness of one or more of the plurality of semiconductor chips 100A1, 100A2, 100A3 and 100A4 may different from another one of the plurality of semiconductor chips 100A1, 100A2, 100A3 and 100A4. For example, the fourth semiconductor chip 100A4 provided in an uppermost portion of the stack of semiconductor chips may have the same width as the first width W1, but may have a larger thickness than the thicknesses of the lower semiconductor chips 100A1, 100A2 and 100A3. For example, a thickness of the fourth semiconductor chip 100A4 may be larger than a thickness of one or more of the first semiconductor chip 100A1, the second semiconductor chip 100A2 and the third semiconductor chip 100A3. Accordingly, the semiconductor chip 100A4 provided in the uppermost portion may perform a heat dissipation function. Meanwhile, a dummy chip for heat dissipation may be further provided on the uppermost semiconductor chip 100A4, and in an example case in which the dummy chip is provided, the dummy chip may have a width equal to or smaller than those of the semiconductor chips 100A1, 100A2, 100A3 and 100A4.

Referring to FIG. 1 together with FIGS. 3A and 3B, the plurality of semiconductor chips 100A1, 100A2, 100A3 and 100A4 may have the same stacked structure.

In an example case in which each of a plurality of semiconductor chips 100A1, 100A2, 100A3 and 100A4 is defined as a unit chip, the unit chip may include a semiconductor substrate 110, a device layer 120 on the semiconductor substrate 110, a through-silicon electrode 130 penetrating through the semiconductor substrate 110. The semiconductor substrate 110 may have a first surface (also referred to as an “active surface”) and a second surface (also referred to as an “inactive surface”) opposite to the first surface. Referring to FIG. 3B, the unit chip may further include lower pads 152 on the device layer 120 (i.e., a lower surface of the unit chip), and upper pads 154 on a second surface (i.e., an upper surface of the unit chip) of the semiconductor substrate 110.

The semiconductor substrate 110 may include silicon. However, the disclosure is not limited thereto, and as such, the semiconductor substrate 110 may include one or more other materials. The semiconductor substrate 110 may include various impurity regions for individual devices and a device isolation structure. The device isolation structure may include, but is not limited to, a shallow trench isolation (STI) structure. The semiconductor substrate 110 may include a metallic material forming a partial wiring structure. The metallic material in the semiconductor substrate 110 may occupy a first area with respect to the total area of the semiconductor substrate 110, and may, for example, satisfy less than 1% of the total area. In some example embodiment, the metallic material in the semiconductor substrate 110 may specifically occupy the first area with respect to the total area of the semiconductor substrate 110 less than 0.2%.

A total coefficient of thermal expansion of the semiconductor substrate 110 may be defined according to a ratio of an area occupied by silicon and an area occupied by the metallic material within the semiconductor substrate 110.

In an example case in which the area occupied by the metallic material in the semiconductor substrate 110 is a %, the total coefficient of thermal expansion may satisfy the following Equation 1.

$$α {1}_{total} = {α}_{m} * a / 100 + {α}_{si} * ( 1 - a / 100 ) \qquad Equation 1$$

In this case, α1ₜₒₜₐₗ may be defined as a total coefficient of thermal expansion of the semiconductor substrate 110, αₛᵢ may be defined as a coefficient of thermal expansion of silicon, and αₘ may be defined as a coefficient of thermal expansion of a metallic material in the semiconductor substrate 110.

As described above, according to embodiment, an amount of expansion of the semiconductor substrate 110 during a process may be determined according to a ratio of the metallic material and the silicon material, for example, an area ratio, in the semiconductor substrate 110.

The semiconductor substrate 110 may be provided to occupy an area smaller than an area of the base structure 300. The semiconductor substrate 110 may have a first width W1 smaller than a width of the base structure 300, and due to a difference in a width between the semiconductor substrate 110 and the base structure 300, a side surface of the semiconductor substrate 110 may be spaced apart from a side surface of the base structure 300 to satisfy a minimum separation distance Dn.

Although a total coefficient of thermal expansion of the semiconductor substrate 110 may be defined according to a ratio of an area occupied by silicon and an area occupied by the metallic material within the semiconductor substrate 110, the disclosure is not limited thereto, and as such, according to another embodiment, a total coefficient of thermal expansion of the semiconductor substrate 110 may be defined according to a ratio of a volume of region occupied by silicon and a volume of region occupied by the metallic material within the semiconductor substrate 110.

The device layer 120 may include a wiring structure 140. According to an embodiment, the wiring structure 140 may be connected to a plurality of individual devices formed on an active surface of the semiconductor substrate 110. As illustrated in FIGS. 3A and 3B, the wiring structure 140 may include a metal wiring layer 142 and a metal via 145. For example, a multilayer wiring structure 140 may have a multilayer structure including two or more metal wiring layers 142 and/or two or more vias 145. The wiring structure 140 may be connected to the lower pads 152 provided on lower surfaces of the semiconductor chips 100A1, 100A2, 100A3 and 100A4.

In the device layer 120, multilayer wiring structures 140 and metal vias 145 may be provided in an insulating layer, and the insulating layer may be formed of an oxide or nitride, and may be preferably formed of silicon oxide (SiOₓ).

The metallic material constituting the multilayer wiring structures 140 and the metal vias 145 in the device layer 120 may occupy a second area with respect to the total area of the device layer 120, and may satisfy, for example, 20% to 60% of the total area and 50% to 60% of the thermal characteristics.

The total coefficient of thermal expansion of the device layer 120 may be defined according to the ratio of the area occupied by the silicon oxide to the area occupied by the metallic material in the device layer 120.

In an example case in which the area occupied by the metallic material in the device layer 120 is b %, the total coefficient of thermal expansion may satisfy the following Equation 2.

$$α {2}_{total} = {α}_{m} * b / 100 + {α}_{beol} * ( 1 - b / 100 ) \qquad Equation 2$$

In this case, α2ₜₒₜₐₗ may be defined as a total coefficient of thermal expansion of the device layer 120, α_{beol} may be defined as a coefficient of thermal expansion of silicon oxide, and αₘ may be defined as a coefficient of thermal expansion of the metallic material in the device layer 120.

As described above, an amount of expansion of the device layer 120 during the process may be determined according to a ratio of the metallic material and the silicon oxide, for example an area ratio, in the device layer 120.

Referring to FIGS. 1 and 2, the device layer 120 may be provided to occupy an area Sd smaller than an area Sa of the semiconductor substrate 110. The device layer 120 may have a second width W2 less than the first width W1 of the semiconductor substrate 110, and due to a difference in a width between the semiconductor substrate 110 and the device layer 120, a side surface of the device layer 120 may be provided to be recessed from the side surface of the semiconductor substrate 110 to satisfy a first separation distance D1. Accordingly, an edge region of the semiconductor substrate 110 may protrude outside the side surface of the device layer 120, and an exposed edge region of the semiconductor substrate 110 may be defined as a dummy region.

The first separation distance D1 may satisfy Equation 3 below.

$$D 1 = T * ( α {2}_{total} - α {1}_{total} ) \qquad Equation 3$$

In this case, T may be defined as a maximum process temperature.

Since a total thermal expansion index (α1ₜₒₜₐₗ) of the semiconductor substrate 110 is substantially the same as a thermal expansion index of a silicon material, the first separation distance D1 varies according to the ratio of the metallic material in the device layer 120.

As described above, a length of expansion of the device layer 120 due to a difference in the coefficient of thermal expansion according to a ratio (e.g., area ratio) of a metallic material between the device layer 120 and the semiconductor substrate 110 may be greater than an expanding length of the semiconductor substrate 110. In order to prevent a defect in which the device layer 120 protrudes to the outside of the side surface of the semiconductor substrate 110 due to a difference in the expansion length between two consecutive layers, the device layer 120 may be provided to be recessed inwardly from the side surface of the semiconductor substrate 110 to satisfy the first separation distance D1.

Accordingly, the side surfaces of the semiconductor substrate 110 and the device layer 120 may form a recess portion G.

Each of the through-silicon vias 130 may have a pillar structure penetrating through the semiconductor substrate 110. An upper end of the through-silicon via 130 may be connected to the upper pads 154, and a lower end of the through-silicon via 130 may be connected to the lower pads 152 through the wiring structure 140. In this manner, the through-silicon via 130 may electrically connect the lower pads 152 and the upper pads 154, respectively. The through-silicon via 130 may include a via plug 135 and an insulating liner 131 surrounding the via plug 135. The insulating liner 131 may electrically separate the via plug 135 from the semiconductor substrate 110.

In a unit chip, each of the semiconductor chips 100A1, 100A2, 100A3 and 100A4, an upper insulating layer 164 may be provided on an upper surface of the semiconductor substrate 110 as an upper passivation layer, and a lower insulating layer 162 may be provided below the device layer 120 as a lower passivation layer, respectively.

As illustrated in FIG. 3B, the upper insulating layer 164 of the semiconductor chips 100A1, 100A2, 100A3 and 100A4 may include a first insulating film 164a and a second insulating film 164b that are sequentially provided. The first insulating film 164a may have a substantially flat upper surface with respect to an upper end of the through-silicon via 130. The upper pads 154 may be formed on the first insulating film 164a and may be connected to the through-silicon via 130. The first insulating film 164a may prevent an undesired electrical connection between the upper pads 154 and the semiconductor substrate 110. According to an embodiment, the upper pads 154 may be provided in the second insulating film 164b. For example, the upper pads 154 may be buried in the second insulating film 164b so that upper surfaces the upper pads 154 are exposed. The exposed upper surfaces of the upper pads 154 may be upper surfaces that are substantially flat with respect to an upper surface of the second insulating film 164b. However, the disclosure is not limited thereto, and as such, according to an example embodiment, the first and second insulating films 164a and 164b may be formed of the same material, but are not limited thereto and may be formed of different materials. For example, the first insulating film 164a may include silicon nitride or silicon oxynitride, and the second insulating film 164b may include silicon oxide. According to another embodiment, the upper insulating layer 164 may include on or more insulating films.

The lower insulating layer 162 may be formed by burying the lower pads 152 in the lower insulating layer 162 such that lower surfaces of the lower pads 152 are exposed. The upper insulating layer 164 and the lower insulating layer 162 may be formed of the same material. For example, the upper insulating layer 164 and the lower insulating layer 162 may include silicon oxide. According to an embodiment, the lower insulating layer 162 may include on or more insulating films.

In the lower insulating layer 162 and the upper insulating layer 164, the metallic material constituting each of the lower pads 152 and the upper pads 154 may occupy a third area with respect to the total area of the lower insulating layer 162 and the upper insulating layer 164, and, for example, may satisfy 1% or less, with respect to the total area. In some example embodiments, the third area may be 0.8% or less with respect to the total area of the lower insulating layer 162 and the upper insulating layer 164.

A total coefficient of thermal expansion of the lower insulating layer 162 and the upper insulating layer 164 may be defined depending on the ratio of an area occupied by silicon oxide or silicon nitride to the area occupied by the metallic material in the lower insulating layer 162 and the upper insulating layer 164.

In an example case in which the area of the metallic material in the lower insulating layer 162 and the upper insulating layer 164 is c % of the overall area of the lower insulating layer 162 and the upper insulating layer 164, the total coefficient of thermal expansion may satisfy the following Equation 4.

$$α {3}_{total} = {α}_{m} * c / 100 + {α}_{SiOx} * ( 1 - c / 100 ) \qquad Equation 4$$

In this case, α3ₜₒₜₐₗ may be defined as a total coefficient of thermal expansion of the lower insulating layer 162 and the upper insulating layer 164, α_{SiOx} is a coefficient of thermal expansion of silicon oxide, and αₘ may be defined as a coefficient of thermal expansion of the metallic material in the lower insulating layer 162 and the upper insulating layer 164.

As described above, an amount of expansion of the lower insulating layer 162 and the upper insulating layer 164 during the process may be determined according to a ratio of the metallic material and silicon oxide, for example, an area ratio, in the lower insulating layer 162 and the upper insulating layer 164.

An area in which the lower insulating layer 162 and the upper insulating layer 164 are substantially bonded is defined as an effective adhesive area, and a second area S2 of the device layer 120 may be defined as an effective functional area.

An effective adhesive area in which the lower insulating layer 162 and the upper insulating layer 164 are bonded to each other may be smaller than the effective functional area of the device layer 120.

Since the topology of an edge region of the lower insulating layer 162 and the upper insulating layer 164 is unstable, an electrode pad connected to an actual device layer 120 and the through-silicon via 130, among the conductive upper and lower pads 152 and 154, may not be provided in the edge region.

The entire lower insulating layer 162 and the entire upper insulating layer 164 may also be provided to occupy an area smaller than an area of the device layer 120. The lower insulating layer 162 and the upper insulating layer 164 may have a third width W3 smaller than the second width W2 of the device layer 120, and due to a difference in a width between the lower insulating layer 162 and the upper insulating layer 164 and the device layer 120, side surfaces of the lower insulating layer 162 and the upper insulating layer 164 may be provided to be recessed from the side surface of the semiconductor substrate 110 to satisfy a second separation distance D2.

The second separation distance D2 may be greater than the first separation distance D1, and the second separation distance D2 of the lower insulating layer 162 may be the same as the second separation distance D2 of the upper insulating layer 164, but the disclosure is not limited thereto.

The second separation distance D2 may satisfy Equation 5 below.

$$D 2 = T * B ( α {3}_{total} - α {1}_{total} ) \qquad Equation 5$$

In this case, T may be defined as a maximum process temperature, and B may be defined as a weight.

As described above, due to a difference in a coefficient of thermal expansion according to the ratio of the metallic material of the lower insulating layer 162 and the upper insulating layer 164 and the semiconductor substrate 110, an expansion length of the lower insulating layer 162 and/or the upper insulating layer 164 during the process may be greater than an expansion length of the semiconductor substrate 110. In order to prevent defects in which the lower insulating layer 162 and the upper insulating layer 164 protrude to the outside of the side surface of the semiconductor substrate 110 due to a difference in an expansion length between two consecutive layers, the lower insulating layer 162 and the upper insulating layer 164 may be provided to be recessed inwardly from the side surface of the semiconductor substrate 110 to satisfy the second separation distance D2, and may be provided to be recessed further inwardly than the device layer 120.

In an example case in which the second separation distance D2 is set to be greater than or equal to the first separation distance D1 between the semiconductor substrate 110 and the device layer 120, a weight B, a ratio value, may be applied, and according to an example embodiment, when any one of the lower insulating layer 162 and the upper insulating layer 164 is set to have a side surface protruding from the side surface of the device layer 120, a resultant weight B may be applied. According to a value of applying the weight B to a difference in a coefficient of thermal expansion between the semiconductor substrate 110, the lower insulating layer 162 and the upper insulating layer 164, a value of the second separation distance D2 may be determined.

The side surface of the semiconductor substrate 110, the lower insulating layer 162 and the upper insulating layer 164 may have a recess portion G thereon, and on the side surface of the semiconductor substrate 110, the device layer 120 and the lower insulating layer 162, a width thereof may decrease as a distance from the upper surface of the semiconductor substrate 110 increases, so that a two-stage recess portion G may be formed. Accordingly, a width of the recess portion G may increase toward the base structure 300.

In this case, since the upper insulating layer 164 provided on the upper surface of the semiconductor substrate 110 may have the same third width W3 as the lower insulating layer 162, a first-stage recess portion G may be further formed on the semiconductor substrate 110.

As each of these semiconductor chips 100A1, 100A2, 100A3 and 100A4 is a unit chip, a width thereof may decrease as it moves downwardly from the semiconductor substrate 110, and the width thereof may decrease as it moves upwardly from the semiconductor substrate 110.

Accordingly, in the semiconductor substrate 110 having a first area S1 larger than the second area S2, an edge region of the first area S1, that is, a region between the second area S2 and the first area S1 exposed to the first separation distance D1, an edge region of the semiconductor substrate 110 protruding outside the side surface of the device layer 120, may be defined as a dummy region.

As described above, the semiconductor substrate 110 has an area larger than the effective functional area and is largely cut to include the dummy region, thereby securing the effective functional area and securing an effective adhesive area so that adhesive force between two unit chips provided vertically may be secured.

Furthermore, distortion may be prevented by mitigating a structural change due to a difference in a coefficient of thermal expansion of each layer according to an area ratio of the metallic material during the process. Furthermore, it may be possible to prevent cracks from occurring in the base structure 300 due to accumulation of morphological stress in the edge region.

Furthermore, since a width W3 of the lower insulation layer 162 and the upper insulation layer 164 is formed to be smaller than the widths W2 and W1 of the device layer 120 and the semiconductor substrate 110 provided above and below, no direct bonding is formed on an edge of a poor morphology. Accordingly, a void may be prevented from occurring in the edge region due to poor morphology, and structural distortion may be suppressed.

According to an example embodiment, a dummy chip for heat dissipation may be further provided on an uppermost portion of the chip stack illustrated in FIG. 1. The dummy chip may have a width W1 equal to or smaller than the width W1 of the semiconductor chips 100A1, 100A2, 100A3 and 100A4, and may have a thickness equal to or similar to that of the semiconductor chips 100A1, 100A2, 100A3 and 100A4. Here, a similar thickness range is not limited thereto, but may be defined as a thickness deviation of ±30%.

In an example case in which the dummy chip is provided, an uppermost surface of the stacked semiconductor chips 100A1, 100A2, 100A3 and 100A4 may be planarized in a polishing process.

Since the thickness of the semiconductor chips 100A1, 100A2, 100A3 100A4 is thin (e.g., 100 μm or less), surface topologies of each chip may be accumulated in a process of stacking the semiconductor chips 100A1, 100A2, 100A3 and 100A4, thus significantly increasing the surface topology of the uppermost surface of the semiconductor chips 100A1, 100A2, 100A3 and 100A4. According to an embodiment, the stacked upper surface (i.e., an uppermost semiconductor chip 100A4 of the semiconductor chips or an upper surface of the cover chip) may be polished to have a flat area, thereby forming a solid bond without poor bonding with the dummy chip.

The dummy chip may include a semiconductor such as silicon or a substrate such as metal. In some example embodiment, the dummy chip may provide a heat dissipation function and/or an identification mark display area.

The upper pads 154 of the plurality of semiconductor chips 100A1, 100A2, 100A3 and 100A4 may be directly-bonded to the lower pads 152 of other semiconductor chips 100A2, 100A3 and 100A4 adjacent to an upper portion of the upper pads 154, respectively.

For example, referring to FIG. 3B, the upper pads 154 and the lower pads 152 are directly bonded between adjacent semiconductor chips 100A2, 100A3 and 100A4, thus forming an “intermetallic bonding DB1.” The intermetallic bonding DB1 may mechanically fix the adjacent semiconductor chips 100A2 and 100B3 to each other, and simultaneously provide a path for transmitting and receiving at least one of a control signal, a power signal, a ground signal, and a data signal. According to an example embodiment, since the intermetallic bonding DB1 of the upper pads 154 and the lower pads 152 does not use an additional conductive bump such as a solder, a transmission loss may be reduced.

As described above, the plurality of semiconductor chips 100A1, 100A2, 100A3 and 100A4 may be electrically connected to each other by the intermetallic bonding DB1 of the upper pads 154 and the lower pads 152.

The upper pads 154 and the lower pads 152 may include the same metal, for example copper (Cu). After the upper pads 154 and the lower pads 152 are pre-bonded to come into contact with each other, the upper pads 154 and the lower pads 152 may be firmly coupled by mutual diffusion of copper through a high-temperature annealing process. The metal forming the upper pads 154 and the lower pads 152 is not limited to copper, and may include other metallic materials (e.g., Au) capable of mutual bonding.

In an example embodiment, a bonding structure BS between adjacent semiconductor chips 100A1, 100A2, 100A3 and 100A4 may include an “inter-dielectric bonding DB2” in addition to the metal bonding DB1 described above. As illustrated in FIG. 3B, the inter-dielectric bonding DB2 may be formed by directly bonding the upper insulating layer 164 on the semiconductor chips 100A1, 100A2, 100A3 and 100A4 and the lower insulating layer 162 of other semiconductor chips 100A2, 100A3 and 100A4 adjacent to an upper portion of the upper insulating layer 164. The inter-dielectric bonding DB2 between the upper insulating layer 164 and the lower insulating layer 162 may be realized by covalent bonding. The bonding structure BS may have a more robust bonding strength by the inter-dielectric bonding DB2. An insulating material forming the upper insulating layer 164 and the lower insulating layer 162 is not limited to silicon oxide, and may include all materials (e.g., SiCN) that may be bonded to each other.

As described above, according to an example embodiment, the bonding structure BS for an inter-chip connection may include the intermetallic bonding DB1 between the lower pad 152 and the upper pad 154, and the inter-dielectric bonding DB2 of the lower insulating layer 162 and the upper insulating layer 164.

In an example embodiment, the base structure 300 may include lower connection pads 352 provided on a lower surface thereof, and upper connection pads 364 provided on an upper surface thereof. According to an example embodiment, the base structure 300 may have a width (i.e., an area) greater than the first width W1 (i.e., an area) of the semiconductor chips 100A1, 100A2, 100A3 and 100A4.

According to an example embodiment, the base structure 300 may be a buffer chip, and similarly to the first semiconductor chips 100A1, 100A2, 100A3 and 100A4, the base structure 300 may include a semiconductor substrate 310, a device layer 320, a through-via 330, upper connection pads 364, and a lower connection pad 352. For example, the device layer 320 may include a logic element. The base structure 300 may have a width or an area greater than those of the first semiconductor chips 100A1, 100A2, 100A3 and 100A4.

A lowermost semiconductor chip 100A1 among the semiconductor chips 100A1, 100A2, 100A3 and 100A4 may be directly bonded onto the base structure 300 similarly to the bonding structure BS described above.

According to an example embodiment, referring to FIG. 3A, the lower pads 152 of the semiconductor chip 100A1 adjacent to the base structure 300 may be directly bonded to upper connection pads 354 to form an intermetallic bonding DB1. The intermetallic bonding DB1 may bond the base structure 300 and the semiconductor chip 100A1 to each other and may ensure an electrical connection at the same time. According to an example embodiment, an upper bonding insulating layer 364 may be formed on an upper surface of the base structure 300, and the upper bonding insulating layer 364 may have an upper surface that is substantially flat with respect to the upper connection pads 354. The upper bonding insulating layer 364 of the base structure 300 and a lower insulating layer 162 of the lowermost semiconductor chip 100A1 may be directly bonded to each other, thus forming an inter-dielectric bonding DB2. In this case, the upper bonding insulating layer 364 may have the same area as the area of the base structure 300, and the lower insulating layer 162 of the lowermost semiconductor chip 100A1 may have a third width W3, so that the lower insulating layer 162 and the upper bonding insulating layer 364 of the lowermost semiconductor chip 100A1 have an area difference and may be hybrid-bonded. That is, the base structure 300 and the lowermost semiconductor chip 100A1 may be hybrid-bonded only in an effective bonding area, similarly to the bonding structure BS. FIG. 1 and FIG. 3A illustrate bonding with the lower connection pads of the first semiconductor chip through the upper connection pads 364, but unlike this, the intermetallic bonding DB1 may be achieved by directly bonding the through-silicon via 130 to adjacent lower pads 152 without upper pads.

The connection bump 370 may be attached to the lower connection pads 352 of the base structure 200. The connection bump 370 may be, for example, a solder ball or a conductive bump. The connection bump 370 may be electrically connected to the semiconductor package 500 and a printed circuit board such as a mother board.

The semiconductor chips 100A1, 100A2, 100A3 and 100A4 may be memory chips. For example, the memory chip may be a volatile memory chip such as a dynamic random access memory (DRAM) or a static random access memory (SRAM), or a nonvolatile memory chip such as a phase-change random access memory (PRAM), a Magnetoresistive random access memory (MRAM), a ferroelectric random access memory (FeRAM), or a resistive random access memory (RRAM). According to an example embodiment, the semiconductor chips 100A1, 100A2, 100A3 and 100A4 may be the same type of memory chip. For example, the semiconductor chips 100A1, 100A2, 100A3 and 100A4 may be high bandwidth memory (HBM) DRAM.

In some other embodiments, some of the semiconductor chips 100A1, 100A2, 100A3 and 100A4 are memory chips, and the others thereof may be logic chips. The logic chip may be, for example, a microprocessor, an analog device, or a digital signal processor.

A molding portion 180 may surround the semiconductor chips 100A1, 100A2, 100A3 and 100A4 on the base structure 300, and may be provided to fill a recess portion G. For example, the molding portion 180 may include an epoxy mold compound (EMC).

An upper surface of the molding portion 180 may be understood as a flat upper surface obtained in a polishing process. Furthermore, a side surface of the molding portion 180 may have a substantially flat coplanar surface with respect to a side surface of the base structure 300. The coplanar side surfaces may be understood as side surfaces obtained in the same cutting process.

The semiconductor package 500 according to the above-described embodiments illustrates a stack of four semiconductor chips, but the number of semiconductor chips to be stacked is not limited thereto. For example, a chip stack may be a stack of more than four semiconductor chips (e.g., 8 and 16).

Since a thickness of the semiconductor chips 100A1, 100A2, 100A3 and 100A4 and the cover chip are thin (e.g., 50 μm or less), in a stacking process by hybrid bonding, morphology defects such as protruding to a side surface or being formed thick due to a difference in the coefficient of thermal expansion between layers may occur due to a high temperature thermal adhesion process.

In order to prevent the morphology defects in the edge region, the semiconductor substrate 110 may protrude outside the device layer 120 to include a dummy region to compensate for the coefficient of thermal expansion, thereby preventing morphology defects due to expansion of the device layer 120.

Furthermore, the third width W3 of the upper and lower bonding layers 164 and 162 may be reduced to minimize a path of external emission during an occurrence of voids, thereby easily removing the voids. Accordingly, the flatness of the semiconductor chips 100A1, 100A2, 100A3 and 100A4 may be improved, and robust inter-dielectric bonding may be ensured.

The above-described example embodiments may be advantageously applied to semiconductor packages having various structures.

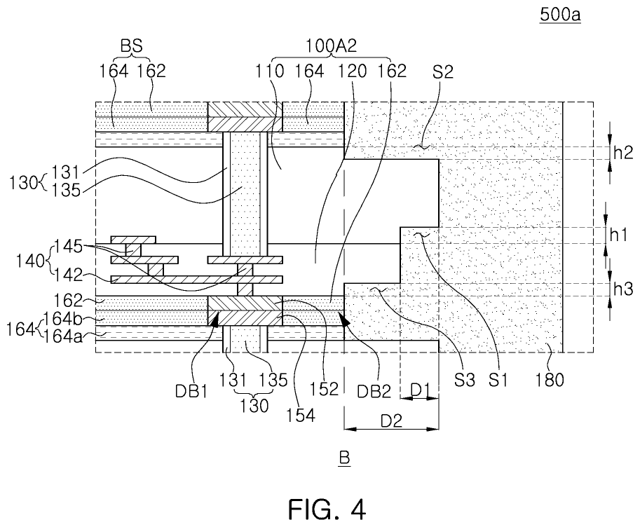

FIG. 4 is a partially enlarged view illustrating a semiconductor package according to an example embodiment of the disclosure, which shows a region corresponding to FIG. 3B.

Referring to FIG. 4, a semiconductor package 500a according to an example embodiment may be understood as having a structure similar to an example embodiment illustrated in FIGS. 1, 2, 3A and 3B, except that a semiconductor substrate 110 and a device layer 120 have step portions S1, S2 and S3. Accordingly, the description of the example embodiment illustrated in FIGS. 1 to 3B may be combined with the description of the example embodiment illustrated in FIG. 4 unless particularly opposed description.

According to an example embodiment, the semiconductor substrate 110 may include a lower edge region having a step portion S1 recessed inwardly along a side surface of the device layer 120 on a lower surface thereof.

A first step portion S1 may be formed to have a first depth h1 between the lower edge region and a lower surface of the semiconductor substrate 110.

The semiconductor substrate 110 may include an upper edge region having a second step portion S2 recessed inwardly along a side surface of the upper insulating layer 164 on an upper surface thereof.

A second step portion S2 may be included to have a second depth h2 between the upper edge region and the upper surface of the semiconductor substrate 110, and the first depth h1 may be equal to or less than the second depth h2.

According to an example embodiment, the device layer 120 may include an edge region having a third step portion S3 recessed inwardly along a side surface of the lower insulating layer 162 on a lower surface thereof.

A third step portion S3 may be formed to have a third depth h3 between the edge region and the lower surface of the device layer 120. The third depth h3 may be equal to or less than the first depth h1.

As described above, the upper and lower surfaces of the semiconductor substrate 110 may have the step portions S1 and S2 with the upper edge region and the lower edge region exposed according to a width difference from upper or lower layers 120 and 164, and the step portions S1 and S2 may be formed by removing a portion of the upper surface or the lower surface of the semiconductor substrate 110 during etching for opening the upper or lower layer.

In an example case in which a thickness of the device layer 120 formed on the lower surface of the semiconductor substrate 110 is greater than a thickness of the upper insulating layer 164 and the lower insulating layer 162, the first depth h1 may have the largest value, but the disclosure is not limited thereto.

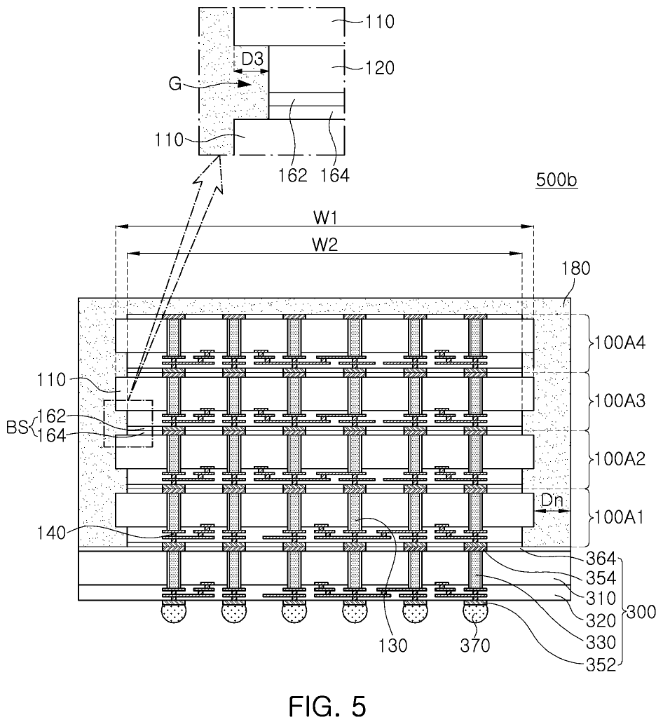

FIG. 5 is a side cross-sectional view illustrating a semiconductor package according to an example embodiment of the disclosure.

A semiconductor package 500b according to an example embodiment may be understood as having a structure similar to that of an example embodiment illustrated in FIGS. 1, 2, 3A and 3B, except that a device layer 120 and upper and lower insulating layers 164 and 162 have the same width W3. Accordingly, the description of the example embodiment illustrated in FIGS. 1, 2, 3A and 3B may be combined with the description of the example embodiment illustrated in FIG. 5 unless particularly opposed description.

According to an embodiment, the semiconductor substrate 110 may have a first width W1 and may be expanded and provided to satisfy a minimum separation distance Dn from a base structure 300.

For example, the device layer 120, the upper insulating layer 164, and the lower insulating layer 162 may have a second width W2, and may have the same area S2 and width W2. Accordingly, an effective adhesive area may be the same as an effective functional area.

A dummy region extending outside the device layer 110 may be included so that the semiconductor substrate 110 has a first width W1 greater than the second width W2.

In this way, the upper insulating layer 164 and the lower insulating layer 162 are formed to have the same second width W2 as the device layer 110, thus securing a larger effective adhesive area.

In an example case in which no difference in the width W2 occurs between the upper insulating layer 164 and the lower insulating layer 162 and the device layer 120, an area ratio of a metallic material between the upper insulating layer 164 and the lower insulating layer 162 and the device layer 120 may satisfy a similar range.

In other words, in the case of some of upper pads 154 and lower pads 152 in the upper insulation layer 164 and the lower insulation layer 162, specifically dummy pads, the pads can be replaced with an insulating layer, and accordingly, in an example case in which only conductive pads remain, an area of the metallic material may be significantly reduced.

In an example case in which the area of the metallic material is reduced in this manner, the upper insulating layer 164 and the lower insulating layer 162 may be formed to the extent that there is little difference in width from the device layer 120, and a third separation distance D3 due to the width difference may be calculated in the same manner as the first separation distance D1 in Equation 3.

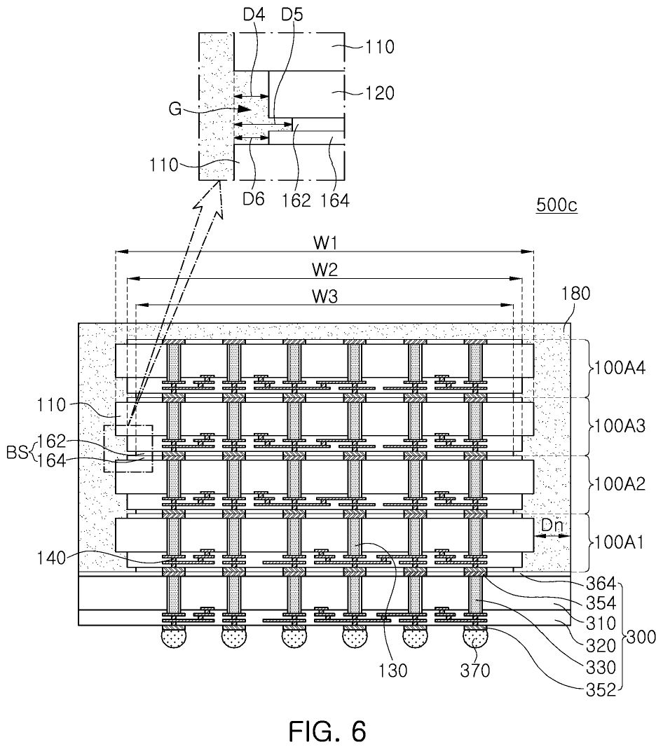

FIG. 6 is a side cross-sectional view illustrating a semiconductor package according to an example embodiment of the disclosure.

A semiconductor package 500c according to an example embodiment may be understood as having a structure similar to the example embodiment illustrated in FIGS. 1, 2, 3A and 3B, except that a width W2 of a device layer 120 and an upper insulating layer 164 are identical. Accordingly, the description of the embodiment illustrated in FIGS. 1, 2, 3A and 3B may be combined with the description of the example embodiment illustrated in FIG. 6 unless particularly opposed description.

According to an embodiment, the semiconductor substrate 110 may have a first width W1, and may be expanded and provided to satisfy a minimum separation distance Dn from the base structure 300.

That is, the device layer 120 and the upper insulating layer 164 may have a second width W2, and the lower insulating layer 162 may have a third width W3 that is smaller than the second width W2. Accordingly, an effective adhesive area may be formed to satisfy the third width W3 and may be the same as that in FIG. 1.

The semiconductor substrate 110 may include a dummy region extending outside the device layer 120 to have a first width W1 that is greater than the second width W2.

In this manner, in an example case in which the areas of the upper insulating layer 164 and the lower insulating layer 162 are different from each other, a path for removing voids occurring between both insulating layers may be dramatically reduced, thereby easily performing void removal while securing the effective adhesive area.

A separation distance D6 between a side surface of the upper insulating layer 164 and a side surface of the semiconductor substrate 110 may be the same as a separation distance D4 between the device layer 120 and the side surface of the semiconductor substrate 110, but the disclosure is not limited thereto, and the separation distance D6 between the side surface of the upper insulating layer 164 and the side surface of the semiconductor substrate 110 may be smaller than a separation distance D5 between a side surface of the lower insulating layer 162 and the side surface of the semiconductor substrate 110.

The separation distances D4, D5 and D6 between each layer can be calculated by referring to Equation 1 to Equation 5 based on a difference between a total coefficient of thermal expansion coefficient of the semiconductor substrate 110 and the coefficients of thermal expansion coefficient of each layer.

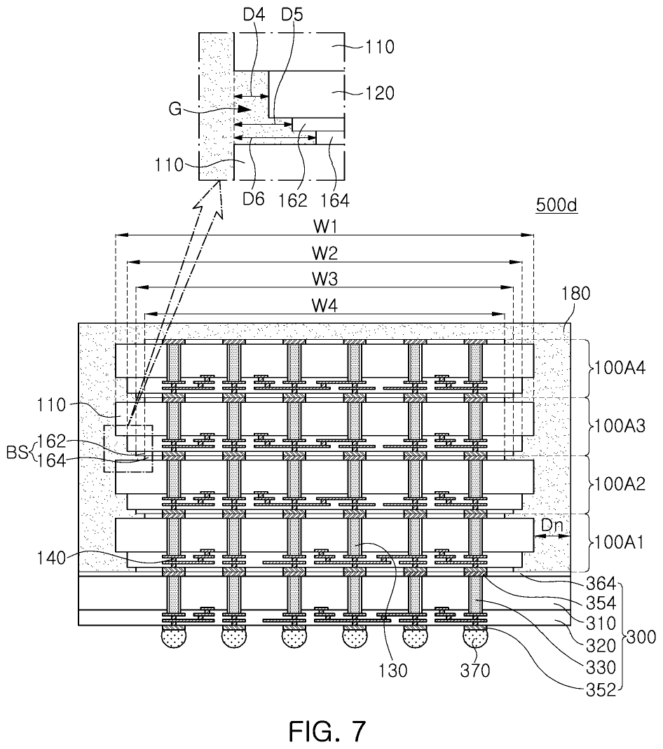

FIG. 7 is a side cross-sectional view illustrating a semiconductor package according to an example embodiment of the disclosure.

A semiconductor package 500d according to an example embodiment may be understood as having a structure similar to the example embodiment illustrated in FIGS. 1, 2, 3A and 3B, except that widths W4 and W3 of an upper insulating layer 164 and a lower insulating layer 162 are different from each other. Accordingly, the description of the embodiment illustrated in FIGS. 1, 2, 3A and 3B may be combined with the description of the example embodiment of the illustration in FIG. 7 unless particularly opposed description.

According to an embodiment, the semiconductor substrate 110 may have a first width W1 and may be expanded and provided to satisfy a minimum separation distance Dn from a base structure 300.

That is, a device layer 120 may have a second width W2 that is smaller than a first width W1, and a lower insulating layer 162 may have the third width W3 that is smaller than the second width W2, and an upper insulating layer 164 may have the fourth width W4 that is smaller than the third width W3. Accordingly, a recess portion G may form three step portions, and a width thereof may decrease as the recess portion G moves downward from the semiconductor substrate 110. Accordingly, an effective adhesive area may be formed to satisfy the fourth width W4.

The semiconductor substrate 110 may include a dummy area extending outside the device layer 120 to have the first width W1 that is larger than the second width W2.

In this manner, in an example case in which areas of the upper insulating layer 164 and the lower insulating layer 162 are different from each other, a path for removing voids occurring between both insulating layers may be dramatically reduced, thereby easily performing void removal while ensuring the effective adhesive area (defined by the fourth width).

A separation distance D6 between a side surface of the upper insulating layer 164 and a side surface of the semiconductor substrate 110 may be greater than a separation distance D5 between a side surface of the lower insulating layer 162 and the side surface of the semiconductor substrate 110.

The separation distances D5 and D6 between each layer can be calculated by referring to Equation 1 to Equation 5 based on a difference between a total coefficient of thermal expansion coefficient of the semiconductor substrate 110 and the coefficients of thermal expansion coefficient of each layer.

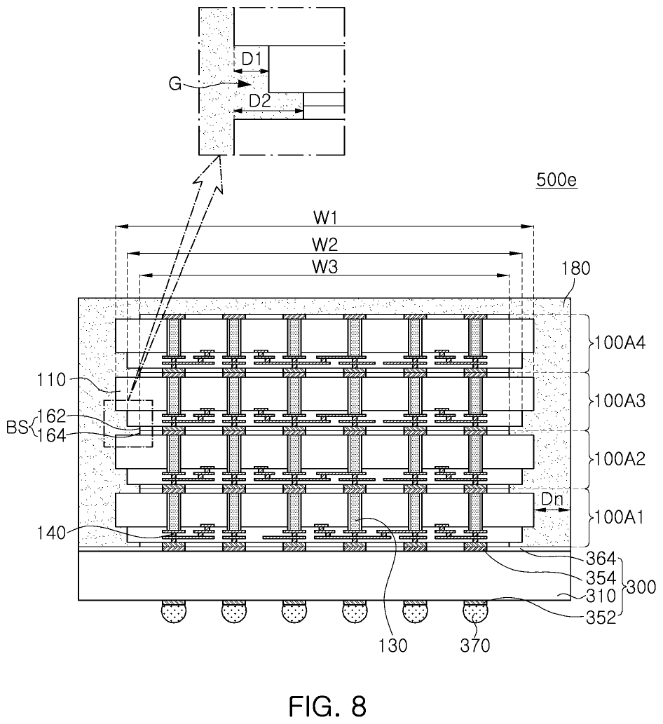

FIG. 8 is a side cross-sectional view illustrating a semiconductor package according to an example embodiment of the disclosure.

In a semiconductor package 500e according to an example embodiment, a base structure 300 may be an interposer for rewiring. The base structure 300 may include a substrate body 310 and a wiring circuit connecting lower connection pads 352 and upper connection pads 354 in the substrate body 310. That is, the semiconductor package 500e is the same as that illustrated in FIGS. 1, 2, 3A and 3B except that the semiconductor package 500e does not include a semiconductor chip and may only include a wire circuit for rewiring.

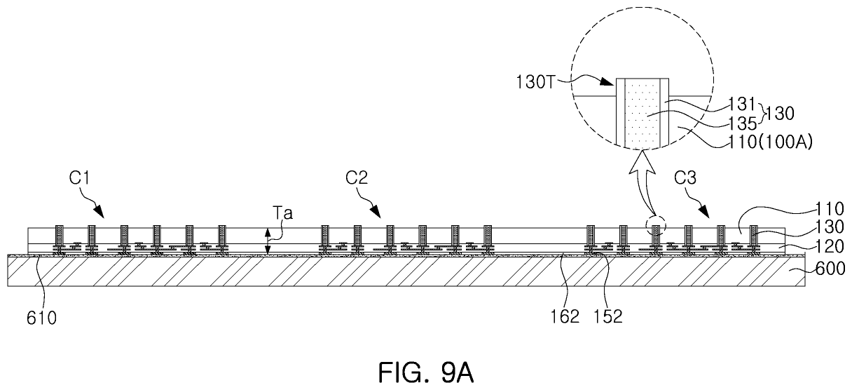

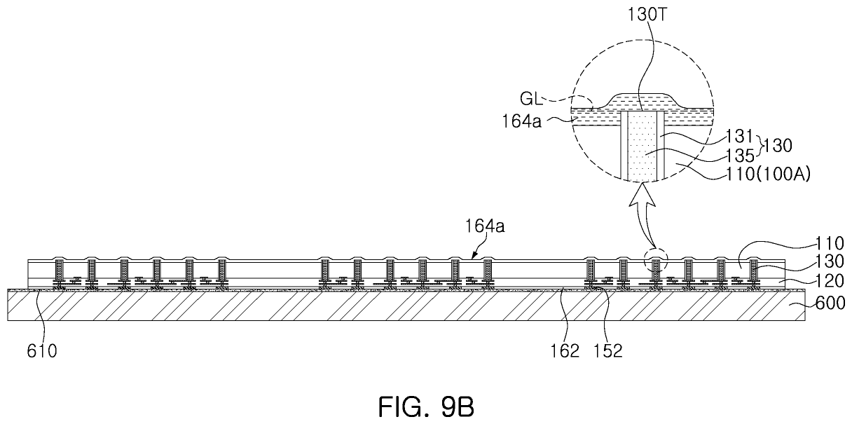

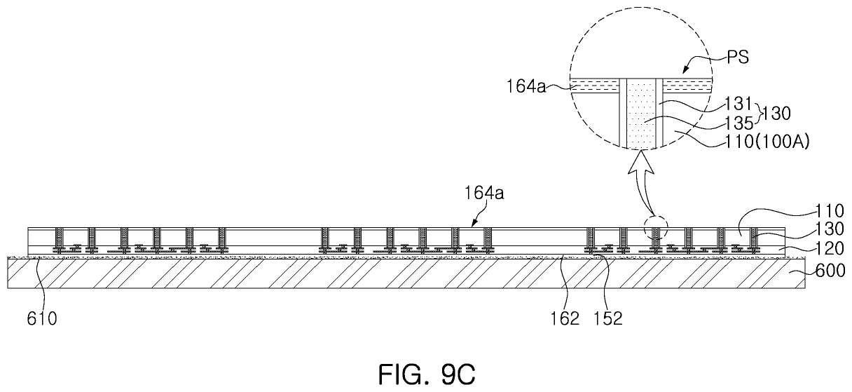

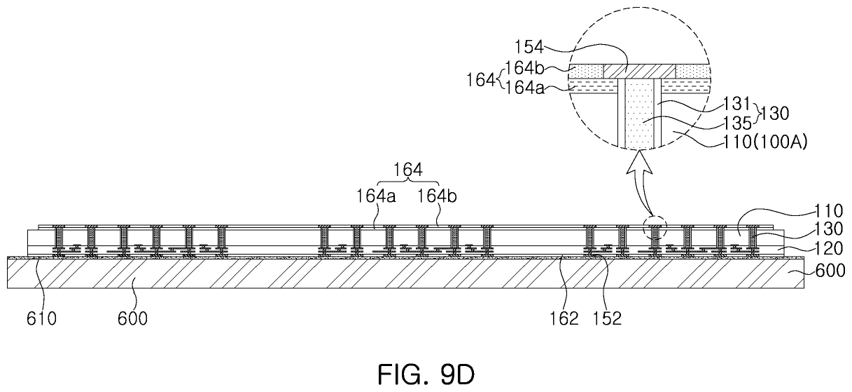

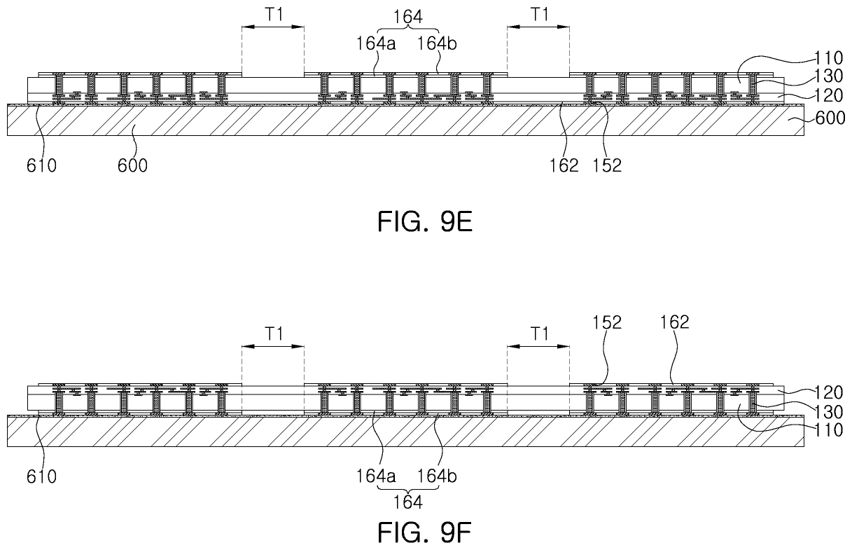

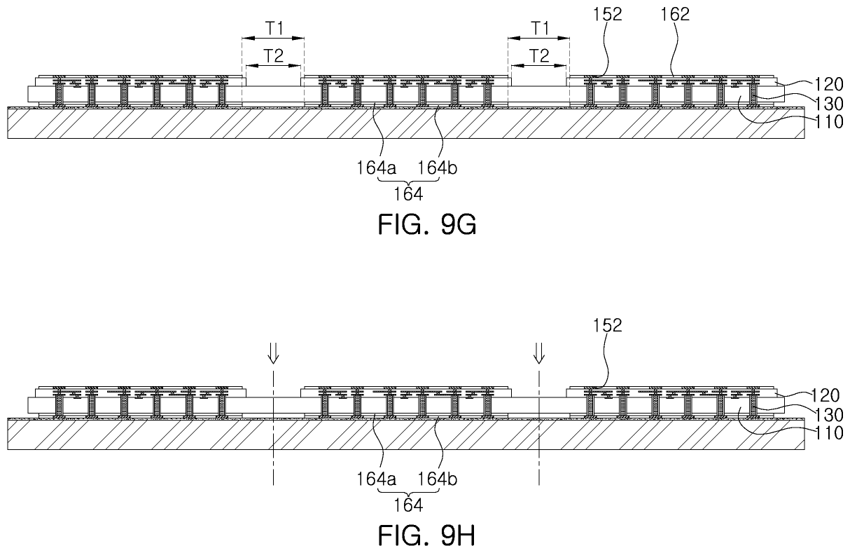

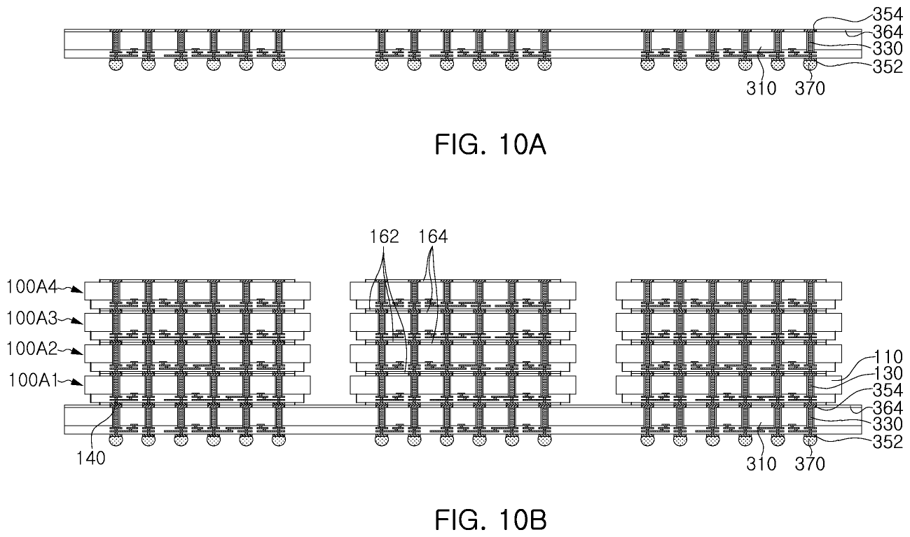

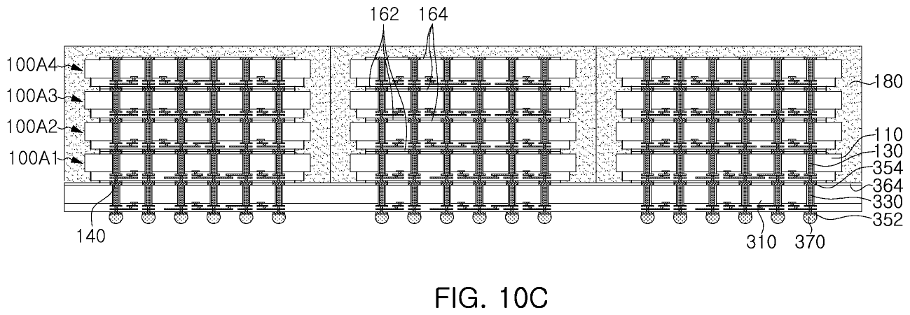

A method of manufacturing a semiconductor package according to an example embodiment may be described with reference to FIGS. 9A to 9H and 10A to 10C. FIGS. 9A to 9H are cross-sectional views of main processes for illustrating a method of manufacturing a semiconductor chip according to an example embodiment of the disclosure, and FIGS. 10A to 10C are cross-sectional views of main processes for illustrating a method of manufacturing a semiconductor package according to an example embodiment of the disclosure.

Referring to FIG. 9A, according to an embodiment, the method may include bonding a semiconductor substrate 110 for a plurality of semiconductor chips 100A onto a carrier substrate 600. According to an embodiment, the bonding may be implemented by an adhesive layer 610 such as a UV curable film. However, the disclosure is not limited thereto, and as such, according to another embodiment, the semiconductor substrate 110 may be provided on carrier substrate 600 in another manner.

For convenience of explanation, the semiconductor substrate 110 is illustrated as a wafer including three semiconductor chips 100A (C1, C2 and C2) A plurality of semiconductor chips may be formed by individual devices on an active surface of the semiconductor substrate 110. Additionally, through-silicon vias 130 extending into the semiconductor substrate 110, a device layer 120 connected to the through-silicon vias 130, and lower pads 152 electrically connected to the through-silicon vias 130 on the device layer 120 may be formed on the active surface of the semiconductor substrate 110. An active surface of the semiconductor substrate 110, that is, a surface on which the device layer 120 is formed, is bonded to face the carrier substrate 600.

The method may further include performing a grinding process on an inactive surface of the semiconductor substrate 110 to adjust a thickness Ta of the semiconductor substrate 110.

According to an embodiment, in the grinding process, an upper end 130T of the through-silicon via 130 may be exposed from a ground surface of a semiconductor wafer. Due to a difference in an etch rate, the upper end 130T of the through-silicon via 130 may protrude from the surface of the semiconductor wafer 100. Through this process, a thickness of the semiconductor chip 100A may be reduced to a desired thickness Ta. This thickness reduction process may also be performed by an etch-back process or a combination thereof in addition to a grinding process such as a chemical mechanical polishing (CMP) process. In some example embodiments, a thickness of the semiconductor substrate 110 may be reduced by performing the grinding process, and the through-silicon via 130 may be sufficiently exposed by applying etch-back under appropriate conditions.

Next, referring to FIG. 9B, the method may include forming a first insulating film 164a on the semiconductor substrate 110. For example, the first insulating film 164a may be formed on the semiconductor substrate 110 and on the exposed upper end 130T of the through-silicon via 130. Here, the first insulating film 164a may be formed on the semiconductor substrate 110 to cover the exposed upper end 130T of the through-silicon via 130.

The first insulating film 164a may be used as a passivation layer. For example, the first insulating layer 164a may include silicon nitride or silicon oxynitride.

Next, referring to FIG. 9C, the method may include performing a grinding operation on the first insulating film 164a. For example, the first insulating film 164a may be ground to expose the through-silicon via 130.

A grinding process may be performed up to a predetermined line GL so that the first insulating film 164a is partially removed and the through-silicon via 130 is sufficiently exposed. Through this grinding process, the first insulating film 164a may have an upper surface that is substantially flat with respect an upper surface of the through-silicon via 130. Additionally, a damaged portion of the upper end 130T of the through-silicon via 130 may also be removed.

As illustrated in FIG. 9D, upper pads 154 are formed on the first insulating film 164a, and a second insulating film 164b is formed to cover the upper pads 154. Next, a grinding process may be performed so that the second insulating film 164b is partially removed to expose upper surfaces of the upper pads 154. Through this grinding process, the second insulating film 164b may have an upper surface that is substantially flat with respect to the upper surfaces of the upper pads 154. For example, the second insulating film 164b may include silicon oxide. In this specification, the first and second insulating films 164a and 164b are collectively referred to as an upper insulating layer 164.

Next, referring to FIG. 9E, the method may further include etching the first and second insulating films 164a and 164b. For example, an edge area of a lower semiconductor substrate 110 may be exposed by partially etching the first and second insulating films 164a and 164b.

According to an embodiment, after forming a mask, dry etching may be performed, and some of the first and second insulating films 164a and 164b may be removed to expose an edge region of the lower semiconductor substrate 110. The first and second insulating films 164a and 164b may be etched to have a first removal width T1. The first removal width T1 may have a value greater than twice the second separation distance D2, but the disclosure is not limited thereto.

Next, referring to FIG. 9F, the semiconductor chip 100 of FIG. 9E may be lifted from the carrier substrate 600, inverted, and attached to the carrier substrate 600.

According to an embodiment, the semiconductor chip 100 may be lifted from the carrier substrate 600 and turned over so that the lower insulating layer 162 of the semiconductor chip 100 is exposed upwardly, and may be provided on the carrier substrate 600.

In a state in which the lower insulating layer 162 is exposed, the mask may be formed and may then be subject to dry etching, and a portion of the lower insulating layer 162 may be removed to have a first removal width T1 equal to the first removal width T1 to expose a portion of the lower device layer 120.

Next, referring to FIG. 9G, in a state in which the lower insulating layer 162 is exposed, the mask may be formed to have a second removal width T2 smaller than the first removal width T1 and may then be subject to laser etching, and a portion of the device layer 120 may be removed to have a second removal width T2 smaller than the first removal width T1. Accordingly, a lower surface of the lower semiconductor substrate 110 may be exposed in a region corresponding to the second removal width T2. In this case, centers of the first removal width T1 and the second removal width T2 may be coaxial.

Next, referring to FIG. 9H, in a state in which the lower insulating layer 162 is exposed, the exposed semiconductor substrate 110 may be cut along a central axis of the first removal width T1 and the second removal width T2. That is, the semiconductor substrate 110 may be cut by performing plasma dicing. Accordingly, the semiconductor substrate 110 may be cut into a plurality of unit chips 100A and may have an edge region protruding laterally from the upper and lower insulating layers 164 and 162 and the device layer 120.

FIGS. 10A to 10C are cross-sectional views of main processes for illustrating a method of manufacturing a semiconductor package according to an example embodiment of the disclosure.

Referring to FIG. 10A, a base structure 300 having a semiconductor substrate 310, a device layer 320, a through-silicon via 330, upper connection pads 354, and lower connection pads 352 is provided.

For convenience of explanation, the base structure 300 is illustrated in a form for manufacturing three semiconductor packages. The base structure 300 may include an upper bonding insulating layer 364 surrounding the upper connection pads 354 on an upper surface thereof. The upper bonding insulating layer 364 may have an upper surface that is substantially flat with respect to upper surfaces of the upper connection pads 354. Connection bumps 370, such as a solder ball, may be formed on the lower connection pads 352 of the base structure 300. Furthermore, in an example embodiment, the base structure 300 may be a buffer chip having a semiconductor substrate 310 implementing a logic chip or a memory chip, upper connection pads 354 and lower connection pads 352 in the top and the bottom of the semiconductor substrate 310, and a through-silicon via 330 connecting the upper connection pads 354 and the lower connection pads 352.

Next, referring to FIG. 10B, individualized semiconductor chips 100A1 are placed on the base structure 300.

The semiconductor chips 100A1 may be semiconductor chips obtained from the process of FIG. 9H. Each of the semiconductor chips 100A1 include lower pads 152, upper pads 154, and through-silicon vias 130 electrically connecting the lower pads 152 and the upper pads 154. Additionally, the semiconductor chips 100A1 include a lower insulating layer 162 provided on the lower surface and surrounding side surfaces of the lower pads 152, and an upper insulating layer 164 provided on the upper surface and surrounding side surfaces of the upper pads 154. This stacking process may perform pre-bonding by applying a certain pressure using a bonding tool. According to an embodiment, the lower pads 152 of the semiconductor chips 100A1 may be directly pre-bonded to the upper connection pads 354 of the base structure 300, respectively, and similarly thereto, the lower insulating layer 162 of the semiconductor chips 100A1 may be directly pre-bonded to the upper bonding insulating layer 364 of the base structure 300. Additional semiconductor chips 100A2, 100A3 and 100A4 may be sequentially stacked, and the dummy chip may be additionally stacked on an uppermost semiconductor chips 100A4, but the disclosure is not limited to thereto.

The dummy chip may also be pre-bonded to the uppermost semiconductor chip 100A4. According to an embodiment, the lower pads and the lower insulating layer of the dummy chip may be directly pre-bonded to the upper connection pads 354 and the upper bonding insulating layer 364 of the uppermost semiconductor chip 100A4, respectively.

In an example case in which the dummy chip is introduced in this process, the topology may be improved by forming the uppermost semiconductor chip 100A4 of the semiconductor chips 100A1, 100A2, 100A3 and 100A4 or a cover chip to a large thickness and then flattening the same, but the disclosure is not limited thereto. An annealing process may be applied to the stacked semiconductor chips 100A1, 100A2, 100A3 and 100A4 to form robust intermetallic bonding through diffusion of metal elements.

Next, referring to FIG. 10C, a molding portion 180 surrounding the semiconductor chips 100A1, 100A2, 100A3 and 100A4 may be formed on the base structure 300, and an upper surface of the molding portion 180 may be partially polished and flattened. Furthermore, an identification mark may be formed on an upper surface of an upper dummy chip, or a heat radiating plate may be formed on the upper dummy chip and the molding portion 180.

The disclosure is not limited to the above-described embodiments and the accompanying drawings but is defined by the appended claims. Therefore, those of ordinary skill in the art may make various replacements, modifications, or changes without departing from the scope of the disclosure defined by the appended claims, and these replacements, modifications, or changes should be construed as being included in the scope of the disclosure.

What is claimed is:

1. A semiconductor package comprising:
a first semiconductor chip having first connection pads provided on a first surface of the first semiconductor chip, and second connection pads provided on a second surface of the first semiconductor chip, the second connection pads electrically connected to the first connection pads; and
at least one second semiconductor chip provided on the first semiconductor chip in a vertical direction, the at least one second semiconductor chip comprising:
a semiconductor substrate having a first width in a first direction,
a device layer provided on a first surface of the semiconductor substrate, the device layer comprising one or more circuit structures and having a second width smaller than the first width in the first direction,
first pads provided on a first surface of the device layer and directly bonded to the second connection pads of the first semiconductor chip,
second pads provided on a second surface of the semiconductor substrate, and
through-silicon vias provided in the semiconductor substrate and configured to electrically connect the first pads and the second pads, the through-silicon vias being connected to the one or more circuit structures.

2. The semiconductor package of claim 1, wherein the first semiconductor chip has a third width greater than the first width.

3. The semiconductor package of claim 1, wherein the at least one second semiconductor chip comprises:
a first insulating layer provided on the first surface of the device layer and on one or more side surfaces of the first pads; and
a second insulating layer provided on a second surface of the semiconductor substrate and on one or more side surfaces of the second pads.

4. The semiconductor package of claim 3, wherein the first insulating layer has a fourth width smaller than the second width.

5. The semiconductor package of claim 3, wherein a side surface of the semiconductor substrate, a side surface of the device layer, and a surface of the first insulating layer form a recess portion, and
wherein a width of the recess portion increases towards the first semiconductor chip.

6. The semiconductor package of claim 3, wherein a first separation distance from a side surface of the semiconductor substrate to a side surface of the device layer is equal to or smaller than a second separation distance from the side surface of the semiconductor substrate to a side surface of the first insulating layer.

7. The semiconductor package of claim 1, wherein a first separation distance from a side surface of the semiconductor substrate to a side surface of the device layer is proportional to a difference between a coefficient of thermal expansion of the semiconductor substrate and a coefficient of thermal expansion of the device layer.

8. The semiconductor package of claim 7, wherein the coefficient of thermal expansion of the semiconductor substrate is based on a ratio of a metallic material of the semiconductor substrate, and the coefficient of thermal expansion of the device layer is based on a ratio of a metallic material of the device layer.

9. The semiconductor package of claim 1, wherein the semiconductor package further comprises:
a molding portion surrounding the at least one second semiconductor chip.

10. The semiconductor package of claim 9, wherein the molding portion is provided in a recess portion formed by a side surface of the semiconductor substrate and a side surface of the device layer.

11. A semiconductor package comprising:
a first semiconductor chip having first connection pads provided on a first surface of the first semiconductor chip, and second connection pads provided on a second surface of the first semiconductor chip, the second connection pads electrically connected to the first connection pads; and
a plurality of second semiconductor chips provided on the first semiconductor chip in a vertical direction, each of the plurality of second semiconductor chips comprising:
a semiconductor substrate having a first width in a first direction,
a device layer provided on a first surface of the semiconductor substrate, the device layer comprising one or more circuit structures and having a second width smaller than the first width in the first direction,
first pads provided on a first surface of the device layer,
second pads provided on a second surface of the semiconductor substrate, and
through-silicon vias provided in the semiconductor substrate and configured to electrically connect the first pads and the second pads, the through-silicon vias being connected to the one or more circuit structures,
wherein the first pads of a lowermost second semiconductor chip, among the plurality of second semiconductor chips, are directly bonded to the second connection pads, and the second pads of the plurality of second semiconductor chips are directly bonded to the first pads of an adjacent second semiconductor chip, among the plurality of second semiconductor chips, and
wherein a recess portion is formed in a side surface of the semiconductor substrate and a side surface of the device layer.

12. The semiconductor package of claim 11, wherein the first semiconductor chip has a third width greater than the first width.

13. The semiconductor package of claim 11, further comprising:
a molding portion provided on the first semiconductor chip and the plurality of second semiconductor chips, and filling the recess portion.

14. The semiconductor package of claim 11, wherein each of the plurality of second semiconductor chips comprises:
a first insulating layer provided on the first surface of the device layer, and a side surface of the first pads; and
a second insulating layer provided on a second surface of the semiconductor substrate, and a side surface of the second pads.

15. The semiconductor package of claim 14, wherein the first insulating layer and the second insulating layer have a fourth width smaller than the first width.

16. The semiconductor package of claim 15, wherein a first separation distance from a side surface of the semiconductor substrate to a side surface of the device layer is proportional to a difference between a coefficient of thermal expansion of the semiconductor substrate and a coefficient of thermal expansion of the device layer.

17. The semiconductor package of claim 14, wherein a width of the first insulating layer is smaller than the second width of the device layer, and a width of the second insulating layer is larger than the width of the first insulating layer.

18. The semiconductor package of claim 14, wherein a width of the second insulating layer is smaller than a second width of the device layer, and a width of the first insulating layer is larger than a width of the second insulating layer.

19. The semiconductor package of claim 14, wherein the semiconductor substrate comprises:
a first step region recessed inwardly from the first surface of the semiconductor substrate along a side surface of the device layer; and
a second step region recessed inwardly from the second surface of the semiconductor substrate along a side surface of the second insulating layer.

20. A semiconductor package comprising:
a first semiconductor chip having first connection pads provided on a first surface of the first semiconductor chip, and second connection pads provided on a second surface of the first semiconductor chip, the second connection pads electrically connected to the first connection pads; and
a plurality of second semiconductor chips provided on the first semiconductor chip in a vertical direction, each of the plurality of second semiconductor chips comprising:
a semiconductor substrate having a first area smaller than a second area of the first semiconductor chip,
a device layer provided on a first surface of the semiconductor substrate, the device layer comprising one or more circuit structures and having a third area smaller than the first area,
first pads provided on a second surface of the semiconductor substrate,
second pads provided on a second surface of the semiconductor substrate, and
through-silicon vias provided in the semiconductor substrate and configured to electrically connecting the first pads and the second pads, the through-silicon vias being connected to the one or more circuit structures,
wherein the first pads of a lowermost second semiconductor chip, among the plurality of second semiconductor chips, are directly bonded to the second connection pads, and the second pads of the plurality of second semiconductor chips are directly bonded to the first pads of an adjacent second semiconductor chip, among the plurality of second semiconductor chips, and
wherein an edge region of the semiconductor substrate protrudes outside a side surface of the device layer.
